(19) United States
(12) Patent Application Publication
(10) Pub. No.: US 2008/0166890 A1
(43) Pub. Date: Jul. 10, 2008

(54) High Pressure Hydrogen Annealing for Mosfet

(76) Inventor: Hyun-Sang Hwang, Gwangju (KR)

Correspondence Address: NATH & ASSOCIATES, 112 South West Street, Alexandria, VA, 22314, US

(21) Appl. No.: 11/885,834

(22) PCT Filed: Mar. 8, 2006
(86) PCT No.: PCT/KR2006/000817

§ 371 Date: Oct. 5, 2007

(30) Foreign Application Priority Data
Mar. 8, 2005 (KR) 10-2005-0019192

(51) Int. Cl. H01L 21/02

(52) U.S. Cl. 438/795; 257/E21.002

(57) ABSTRACT

The present invention relates to a high pressure hydrogen annealing method for MOSFET semiconductor device, and more particularly, to effectively remove a supersaturated hydrogen on a high-k insulating layer treated by a high pressure hydrogen annealing so that the reliability of a device is improved. In other words, in order to decrease an interfacial charge, it is required to perform a high density and a high pressure hydrogen annealing. In this case, a hydrogen is included at an interface and a bulk of a high-k insulating layer, resulting in improving the initial operational characteristics of a device by passivating interfacial charge existing at an interface, but deteriorating the reliability of a device due to the hydrogen remaining in the insulating bulk. Therefore, in the present invention, a high pressure hydrogen annealing is performed and the subsequent annealing is performed under an inert gas atmosphere for a long time to effectively remove hydrogen molecules remaining at the bulk.

### TECHNICAL FIELD

The present invention relates to a high pressure hydrogen annealing method for MOSFET semiconductor device, and more particularly, to effectively remove a super-saturated hydrogen on a high-k insulating layer treated by a high pressure hydrogen annealing so that the reliability of a device is improved.

### BACKGROUND ART

In a process for manufacturing a semiconductor device using the existing SiO₂ as a gate insulating layer, a metallization process is completed and an annealing is carried out for 10 to 30 minutes under a forming gas atmosphere including about a 3˜4% hydrogen at 400˜450° C. to passivate an interfacial state at an interface by a hydrogen and to lower the density of an interfacial charge below 10¹¹/cm²-eV. Therefore, it is possible to obtain excellent charge mobility characteristics. However, in a case that a high-k gate insulating layer is used, there exist much higher (for example, more than 10˜100 times) interfacial charge and fixed charge than SiO₂ prior to annealing. Thus, in order to solve the above problems, it is required to perform an annealing under a hydrogen atmosphere with a relatively high density and a high temperature. According to a research (page 613) published on IEDM on December, 2002 by professor Jack Lee at University of Texas at Austin, in order to improve interfacial charge characteristics of a high-k insulating layer, an insulating layer is formed and treated by an annealing under a 4% hydrogen/deuterium atmosphere at a high temperature of 600˜700° C. and then a metallization is performed. In this case, an annealing is performed prior to a metallization because a melting temperature of A1 is relatively low not to be raised over 450° C. after the metallization. In addition, a hydrogen with a low density such as below than 4% is used in the annealing under an atmosphere pressure in general, because a hydrogen with more than 5% density can be exploded.

However, the process has problems as follows,

First, an annealing process with a forming gas at a high temperature applied to a high-k insulating layer prior to a metallization can passivate an interface and a fixed charge but increase an effective thickness due to a high temperature process to crystallize it. In addition, a leakage current characteristic may be degraded. Therefore, it is necessary to maintain a process at a low temperature.

Second, even though a passivation is carried out prior to a metallization, a metallization process causes plasma defects to increase interfacial charges again.

Therefore, the idealist method is to effectively passivate an interface of a high-k insulating layer at a low temperature after the metallization is performed.

In other words, in a case of a standard semiconductor process using the existing SiO₂ insulating layer, an interfacial charge of the insulating layer is decreased by an annealing under a forming gas (with hydrogen of 3%/Ar of 97%) atmosphere for 30 minutes at 450° C. at the final step of a semiconductor device to improve mobility characteristics of a MOSFET device.

However, in a case of a high-k gate insulting layer, an annealing at a low temperature cannot lower an interfacial state sufficiently. If a temperature is raised, a thermally unstable high-k is reacted to increase the thickness of a layer. In other words, the desired passivation effects are not obtained under a low hydrogen atmosphere in the existing high pressure process. In a case that an annealing is carried out under a high pressure and 100% hydrogen atmosphere in order to solve it, a desired passivation is obtained to improve electric characteristics of a device according to the inventor of this application(in Korean application No. 2003-43709). However, the reliability of a device may be deteriorated.

In other words, in order to decrease an interfacial charge, it is required to perform a high density and a high pressure hydrogen annealing. In this case, a hydrogen is included at an interface and a bulk of a high-k insulating layer, resulting in improving the initial operational characteristics of a device by passivating interfacial charge existing at an interface, but deteriorating the reliability of a device due to the hydrogen remaining in the insulating bulk.

### DISCLOSURE OF INVENTION

### Technical Problem

The present invention is provided in order to solve the above problems. An object of the present invention is to provide with a method for performing a high pressure hydrogen annealing and the subsequent annealing under an inert gas atmosphere in order to solve electric characteristics and reliability characteristics of a MOSFET device simultaneously using a high-k gate insulating layer.

### Technical Solution

In order to achieve the object of the present invention, a high pressure hydrogen annealing method for a MOSFET semiconductor device according to the present invention is characterized by that electric characteristics of the semiconductor device are improved through an annealing process with a different atmosphere gas consisting of two steps.

It is preferable that the annealing is carried out under an atmosphere pressure of 2˜50 in the first step.

It is preferable that the annealing is carried out at a temperature of 400° C.˜500° C. in the first step.

It is preferable that a gas atmosphere of the first step is of 100% hydrogen.

It is preferable that a gas atmosphere of the first step is of 100% deuterium.

It is preferable that the annealing of the second step is carried out under an atmosphere pressure of 1˜10.

It is preferable that the annealing in the second step is carried out at a temperature of 400° C.˜500° C.

It is preferable that a gas atmosphere in the second step is of 100% nitrogen.

It is preferable that a gas atmosphere in the second step is of 100% argon.

The present invention is characterized by that a supersaturated hydrogen on a high-k insulating layer treated by a high pressure hydrogen annealing is effectively removed so that the reliability of a device is improved.

The present invention is characterized by that a high pressure hydrogen annealing is performed to include a large amount of hydrogen at an interface and a bulk and the subsequent annealing is performed under an inert gas atmosphere for a long time to effectively remove hydrogen molecules remaining at the bulk at the state that hydrogen at an interface determining the initial characteristics of a device is not affected.

The present invention is characterized by that a high pressure hydrogen annealing is performed under a hydrogen and deuterium atmosphere with a high density (100%) and a high pressure (more than 10 atmosphere) at a relatively low temperature below than 450° C. to effectively passivate an interface/a fixed charge of a high-k insulating layer after the metallization is performed and further to provide an insulating layer with a large amount of hydrogen/deuterium in order to passivate an interfacial charge and a fixed charge, resulting in improving the characteristics of a device. Especially, a deuterium is used rather than hydrogen to improve the reliability of a device under an electric stress due to a heavy mass effect of a deuterium. Next, an annealing is performed under an inert gas atmosphere such as argon and nitrogen to remove the remaining hydrogen atom.

### Advantageous Effects

As described above, according to the present invention, a high pressure hydrogen annealing is performed to include a large amount of hydrogen at an interface and a bulk and the subsequent annealing is performed under an inert gas atmosphere for a long time to effectively remove hydrogen molecules remaining at the bulk at the state that hydrogen at an interface determining the initial characteristics of a device is not affected.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a graph showing an electric characteristic of a MOSFET device where a high pressure hydrogen annealing and the subsequent nitrogen treatments are carried out in accordance with an embodiment of the present invention.

FIG. 2 is a graph showing an interfacial charge density according to a process measured by a charge pumping in accordance with an embodiment of the present invention.

FIG. 3 is a graph showing a change of a threshold voltage according to a process under FN stress in accordance with an embodiment of the present invention.

FIG. 4 is a graph showing a change of a threshold voltage according to a process under a Hot electron stress in accordance with an embodiment of the present invention.

FIG. 5 shows a model for improving the reliability of a device according to subsequent processes in accordance with an embodiment of the present invention.

### BEST MODE FOR CARRYING OUT THE INVENTION

The preferred embodiments of the present invention now will be described in detail with reference to the accompanying drawings hereinafter. In every drawing, the same reference numerals denote the same components. The detailed descriptions of the well-known functions and the constructions which are determined to make the spirit of the present invention unclear will be omitted.

### Embodiment 1

A MOS device is manufactured using the processes as follows,

1. HfO₂ gate insulating layer is formed using an atomic layer deposition ALD process.

2. A MOS device is manufactured by applying the final metallization process.

3. A specimen is put in a closed vessel and an annealing is performed under 100% hydrogen or deuterium atmosphere with a process temperature of 450° C. and a process pressure of 20 atmosphere for 30 minutes.

4. A specimen is put in a closed vessel and an annealing is performed under a nitrogen or argon atmosphere with a process temperature of 450° C. and a process pressure of 10 atmosphere for 30 minutes.

### Embodiment 2

A MOS device is manufactured using the processes as follows,

1. HfO₂ gate insulating layer is formed using an atomic layer deposition ALD process.

2. A MOS device is manufactured by applying the final metallization process.

3. A specimen is put in a closed vessel and an annealing is performed under 100% hydrogen or deuterium atmosphere with a process temperature of 450° C. and a process pressure of 20 atmosphere for 30 minutes.

4. A specimen is put in an open tube-furnace and an annealing is performed under a nitrogen or argon atmosphere with a process temperature of 450° C. and a process pressure of 10 atmosphere for 30 minutes.

As a result of comparing a specimen treated by the existing high pressure hydrogen annealing with a device applied by the subsequent annealing, the improved characteristics have been confirmed as follows,

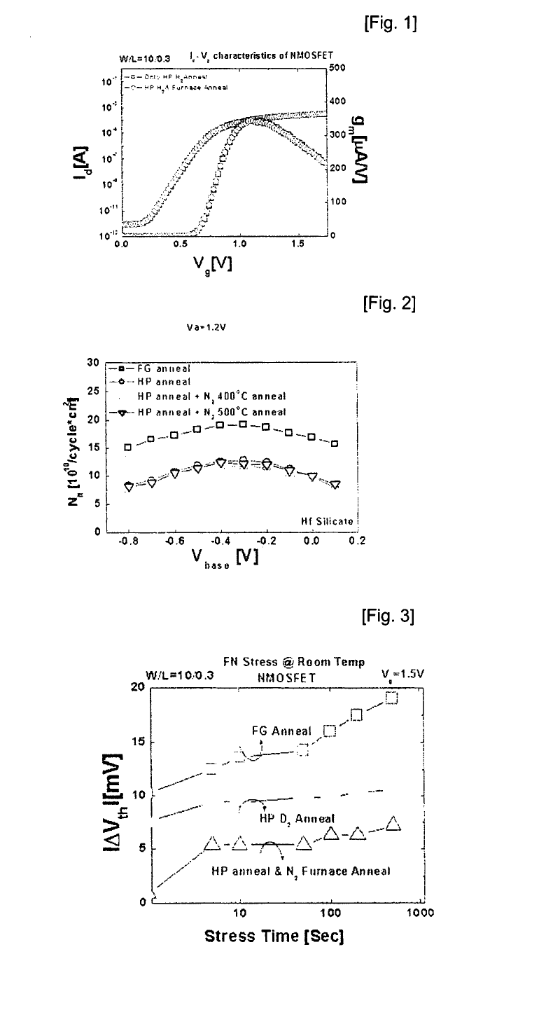

1. It is confirmed that the initial operational characteristics of a MOSFET device was not changed by the subsequent annealing. (FIG. 1)

2. It is confirmed that an interfacial charge density is improved by a high pressure hydrogen annealing in comparison with a specimen treated by the existing forming gas and is not changed by the subsequent annealing as a result of confirmation by a charge-pumping method. (FIG. 2)

3. In comparing a change of a threshold voltage by a FN stress, the specimen treated by a high pressure hydrogen and the subsequent annealing shows the highest reliability. (change of a low threshold voltage) (FIG. 3)

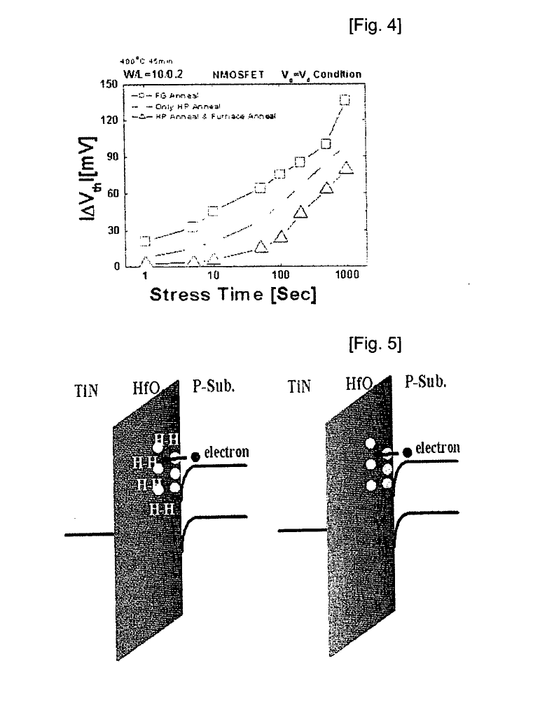

4. In comparing a change of a threshold voltage by a Hot electron stress, the specimen treated by a high pressure hydrogen and the subsequent annealing shows the highest reliability. (change of a low threshold voltage) (FIG. 4)

The present invention has been described with reference to the preferred embodiments, but it is apprehended that the present invention can be modified and changed within the spirit and scope described in the claims into various ways to those skilled in the art.

1. A high pressure hydrogen annealing method for a MOSFET semiconductor device,
wherein electric characteristics of the semiconductor device are improved through an annealing process with a different atmosphere gas consisting of two steps.

2. The method of the claim 1, wherein the annealing is carried out under an atmosphere pressure of 2˜50 in the first step.

3. The method of the claim 1, wherein the annealing is carried out at a temperature of 400° C.˜500° C. in the first step.

4. The method of the claim 1, wherein a gas atmosphere of the first step is of 100% hydrogen.

5. The method of the claim 1, wherein a gas atmosphere of the first step is of 100% deuterium.

6. The method of the claim 1, wherein the annealing of the second step is carried out under an atmosphere pressure of 1˜10.

7. The method of the claim 1, wherein the annealing in the second step is carried out at a temperature of 400° C.˜500° C.

8. The method of the claim 1, wherein a gas atmosphere in the second step is of 100% nitrogen.

9. The method of the claim 1, wherein a gas atmosphere in the second step is of 100% argon.
